(19) United States
(12) Patent Application Publication
(10) Pub. No.: US 2023/0325121 A1
(43) Pub. Date: Oct. 12, 2023

(54) MEMORY CONTROLLER, CONTROL METHOD FOR CONTROLLING MEMORY CONTROLLER, AND STORAGE MEDIUM

(71) Applicant: CANON KABUSHIKI KAISHA, Tokyo (JP)

(72) Inventor: DAISUKE SHIRAISHI, Tokyo (JP)

(21) Appl. No.: 18/189,104

(22) Filed: Mar. 23, 2023

(30) Foreign Application Priority Data
Mar. 29, 2022 (JP) 2022-053738

(51) Int. Cl. G06F 3/06

(52) U.S. Cl. CPC G06F 3/0659; G06F 3/0604; G06F 3/0673

(57) ABSTRACT

A memory controller includes a storing unit configured to store one or more read or write access requests, a first generation unit configured to generate a read command or write command based on the access requests stored in the storing unit, a second generation unit configured to generate a page control command based on the access requests stored in the storing unit, and an issuance unit configured to, in a case where the read command or the write command generated by the first generation unit and the page control command generated by the second generation unit conflict with each other, then based on access requests in which pages are already opened among the access requests stored in the storing unit, issue either of the read command or the write command generated by the first generation unit and the page control command generated by the second generation unit to a memory.

### FIELD

The present disclosure relates to a memory controller, a control method for controlling a memory controller, and a storage medium.

### DESCRIPTION OF THE RELATED ART

As a main storage device of a computer system, generally, a dynamic random-access memory (DRAM) is used. With the enhanced functions and enhanced performance of the computer system, a demand for the performance of the DRAM increases. To maximize the performance of the DRAM, various techniques for a memory controller are discussed.

At the timing when a command is issued to the DRAM, if a request to issue a read/write command and a request to issue a page control command such as an active command or a pre-charge command to different banks are simultaneously present, it is necessary to select and issue either of the commands. The command that is not selected cannot be issued until the timing when a command can be issued to the DRAM next.

The publication of Japanese Patent Application Laid-Open No. 2020-057110 discusses a command control system that selectively switches a first preferential mode and a second preferential mode. The first preferential mode is a mode for changing the output timing of a row address strobe (RAS) command without changing the output timing of a column address strobe (CAS) command. The second preferential mode is a mode for changing the output timing of a CAS command without changing the output timing of a RAS command.

The publication of Japanese Patent Application Laid-Open No. 2020-057110 does not discuss a method for switching the first and second preferential modes. In the first preferential mode, if a read/write command that is preferentially issued is completed before a read/write command for an active command that is issued later starts, a gap occurs in a data bus, and the use efficiency of a memory decreases. In the second preferential mode, if the number of read/write commands that are issued later is greater than the number of read/write commands that can be issued, a gap due to the delay of the issuance of the read/write commands occurs in the data bus, and the use efficiency of the memory decreases.

### SUMMARY

The present invention is directed to preventing a decrease in the use efficiency of a memory.

According to an aspect of the present disclosure, a memory controller that issues a command to access a memory including a plurality of banks includes a storing unit configured to store one or more read or write access requests, a first generation unit configured to generate a read command or a write command based on the access requests stored in the storing unit, a second generation unit configured to generate a page control command based on the access requests stored in the storing unit, and an issuance unit configured to, in a case where the read command or the write command generated by the first generation unit and the page control command generated by the second generation unit conflict with each other, then based on access requests in which pages are already opened among the access requests stored in the storing unit, issue either of the read command or the write command generated by the first generation unit and the page control command generated by the second generation unit to the memory.

Further features of the present disclosure will become apparent from the following description of exemplary embodiments with reference to the attached drawings.

### BRIEF DESCRIPTION OF THE DRAWINGS

FIG. 1 is a diagram illustrating an example of a configuration of a memory controller.

FIG. 2 is a diagram illustrating an example of a configuration of an entry in an access storing circuit.

FIG. 3 is a diagram illustrating an example of a configuration of a priority control circuit.

FIG. 4 is a flowchart illustrating a command selection algorithm.

FIGS. 5A and 5B are diagrams illustrating operation examples where an active command is selected.

FIGS. 6A and 6B are diagrams illustrating operation examples where a read command is selected.

FIGS. 7A and 7B are diagrams illustrating operation examples where a pre-charge command is selected.

FIGS. 8A and 8B are diagrams illustrating operation examples where a read command is selected.

FIGS. 9A and 9B are diagrams illustrating operation examples where an active command is selected.

FIGS. 10A and 10B are diagrams illustrating operation examples where a read command is selected.

FIGS. 11A and 11B are diagrams illustrating operation examples where a pre-charge command is selected.

FIGS. 12A and 12B are diagrams illustrating operation examples where a read command is selected.

FIG. 13 is a diagram illustrating an example of a configuration of an entry in an access storing circuit.

FIG. 14 is a flowchart illustrating a command selection algorithm.

### DESCRIPTION OF THE EMBODIMENTS

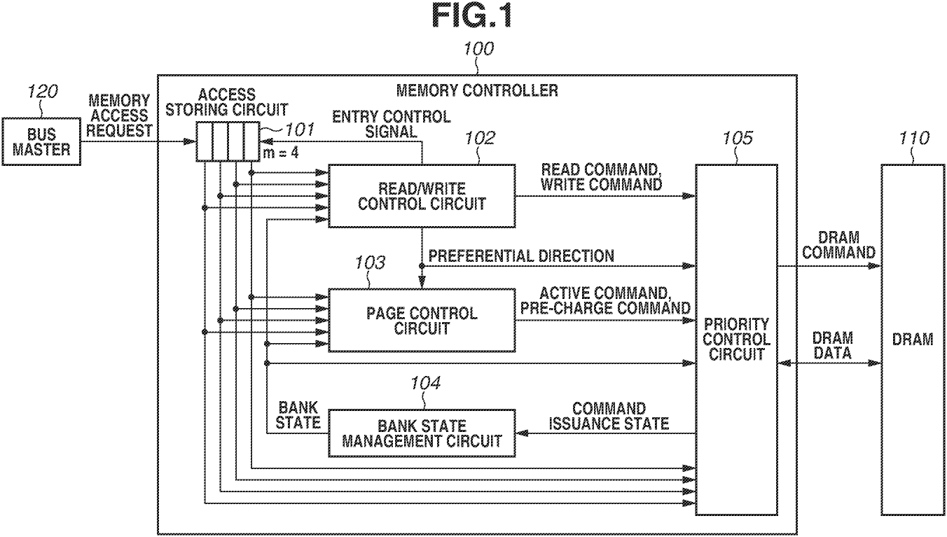

FIG. 1 is a diagram illustrating an example of the configuration of a memory controller 100 according to a first exemplary embodiment. The memory controller 100 includes an access storing circuit 101, a read/write control circuit 102, a page control circuit 103, a bank state management circuit 104, and a priority control circuit 105.

The memory controller 100 is connected to a dynamic random-access memory (DRAM) 110 including a plurality of banks, and a bus master 120. The bus master 120 transmits a memory access request including address information to the memory controller 100. The memory access request includes the address information and/or write data. The memory controller 100 generates a DRAM command based on the memory access request received from the bus master 120 and transmits the generated DRAM command to the DRAM 110. The memory controller 100 transfers data to the DRAM 110 based on the transmitted DRAM command.

First, the access storing circuit 101 is described. The access storing circuit 101 is a buffer capable of storing a plurality of access requests to the DRAM 110 (hereinafter, “memory access requests”). The access storing circuit 101 includes m (m ≥ 2) entries. The memory controller 100 does not depend on the number of m.

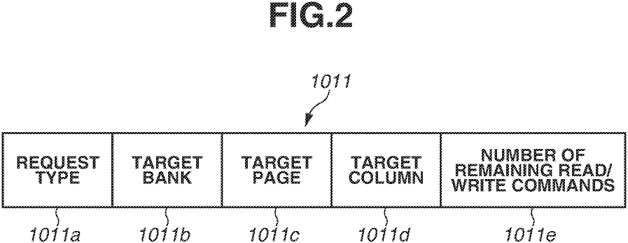

FIG. 2 is a diagram illustrating an example of the configuration of an entry 1011 in the access storing circuit 101. In the access storing circuit 101, m entries 1011 as illustrated in FIG. 2 are present. The entry 1011 includes a “request type” field 1011a, a “target bank” field 1011b, a “target page” field 1011c, a “target column” field 1011d, and a “number of remaining read/write commands” field 1011e.

The bus master 120 transmits a memory access request to the memory controller 100. The access storing circuit 101 receives the memory access request from the bus master 120, converts the received memory access request to correspond to the fields 1011a to 1011e, and stores the fields 1011a to 1011e.

The request type 1011a indicates the type of the memory access request stored in the entry 1011. The request type 1011a indicates “WRITE” with which the memory access request indicates the writing of write data to the DRAM 110 or “READ” with which the memory access request indicates the reading of read data from the DRAM 110.

The target bank 1011b indicates a bank address in the DRAM 110 to be accessed by the memory access request stored in the entry 1011.

The target page 1011c indicates a page address in the DRAM 110 to be accessed by the memory access request stored in the entry 1011.

The target column 1011d indicates a beginning column address in the DRAM 110 to be accessed by the memory access request stored in the entry 1011.

The number of remaining read/write commands 1011e indicates the number of remaining read/write commands in the DRAM 110 to be executed according to the memory access request stored in the entry 1011.

The DRAM 110 includes a plurality of banks. Each of the plurality of banks includes a plurality of memory cells and is identified by a bank address. Data can be written to or read from each of the plurality of memory cells, and each of the plurality of memory cells is identified by a page address or a column address.

In a case where the memory controller 100 stores a memory access request in the access storing circuit 101, the memory controller 100 stores a new memory access request in the entry 1011 following the end of a stored memory access request. In a case where the memory controller 100 reads a memory access request from the access storing circuit 101, the memory controller 100 can read a memory access request from any entry 1011.

Next, an entry control signal input from the read/write control circuit 102 to the access storing circuit 101 is described. The entry control signal includes an entry number field, a deletion field, and an update field. If 1 is set in the deletion field, the access storing circuit 101 deletes the entry 1011 indicated by the entry number field. If 1 is set in the update field, the access storing circuit 101 updates the target column 1011d in the entry 1011 indicated by the entry number field to a beginning column address to be accessed by a next DRAM command. Then, the access storing circuit 101 updates the number of remaining read/write commands 1011e to a value obtained by subtracting 1.

Next, the read/write control circuit 102 is described. The read/write control circuit 102 can reference all memory access requests stored in the access storing circuit 101. The read/write control circuit 102 selects, among the memory access requests stored in the access storing circuit 101, any memory access request from memory access requests in which pages to be accessed by the memory access requests are opened. The determination of whether a page to be accessed by a memory access request is opened is made based on the target bank 1011b and the target page 1011c in the entry 1011 and a bank state generated by the bank state management circuit 104. Then, the read/write control circuit 102 generates a read command or a write command based on the selected memory access request and outputs the read command or the write command to the priority control circuit 105. To prevent a read/write switching penalty, the read/write control circuit 102 according to the present exemplary embodiment selects a memory access request to successively issue a read command and a write command.

Then, the read/write control circuit 102 outputs a preferential direction indicating which of read access and write access is currently preferentially selected to the page control circuit 103 and the priority control circuit 105.

Next, a procedure is described in which the read/write control circuit 102 generates an entry control signal.

If the read/write control circuit 102 issues the last read command or write command to be executed according to a memory access request, the processing of the corresponding memory access request is completed. Thus, the read/write control circuit 102 generates an entry control signal to delete the corresponding entry 1011 from the access storing circuit 101. If, on the other hand, the read/write control circuit 102 issues a read command or a write command that is not the last, the read/write control circuit 102 generates an entry control signal to update the corresponding entry 1011 in the access storing circuit 101. If, however, the read/write control circuit 102 issues the last read command or write command, the read/write control circuit 102 does not need to update the corresponding entry 1011. The determination of whether the issued read command or write command is the last is made based on whether the number of remaining read/write commands 1011e in the entry 1011 is 1.

Next, the page control circuit 103 is described. The page control circuit 103 can reference all the memory access requests stored in the access storing circuit 101. To the page control circuit 103, the memory access requests stored in the access storing circuit 101, the bank state output from the bank state management circuit 104, and the preferential direction output from the read/write control circuit 102 are input. The page control circuit 103 generates a page control command as an active command or a pre-charge command based on the memory access requests stored in the access storing circuit 101, the bank state, and the preferential direction. Then, the page control circuit 103 outputs the active command or the pre-charge command to the priority control circuit 105.

The active command is a command to specify a bank address and a page address to be accessed from now, open (enable) the specified page in the specified bank, and prepare a read or write operation. The pre-charge command is a command to close (disable) a page in a bank opened by an active command.

Next, the bank state management circuit 104 is described. The bank state management circuit 104 updates the bank state based on a command issuance state input from the priority control circuit 105 and outputs the bank state to the read/write control circuit 102, the page control circuit 103, and the priority control circuit 105. The command issuance state includes the command type of a command issued to the DRAM 110 and a bank and a page for which the command is issued. The bank state includes, with respect to each of the banks included in the DRAM 110, information indicating whether a page is opened and the page address of the opened page.

Finally, the priority control circuit 105 is described. The priority control circuit 105 can reference all the memory access requests stored in the access storing circuit 101. To the priority control circuit 105, the memory access requests stored in the access storing circuit 101, the bank state output from the bank state management circuit 104, and the preferential direction output from the read/write control circuit 102 are input, and the priority control circuit 105 generates a page-opened memory access amount. The priority control circuit 105 selects one of a read command or a write command input from the read/write control circuit 102 and a page control command input from the page control circuit 103 based on the page-opened memory access amount and issues the selected command to the DRAM 110. Although not illustrated in FIG. 1, the priority control circuit 105 may also select a refresh command together with the above command. The priority control circuit 105 also outputs the command issuance state including the command type of the command issued to the DRAM 110 and a bank and a page for which the command is issued to the bank state management circuit 104.

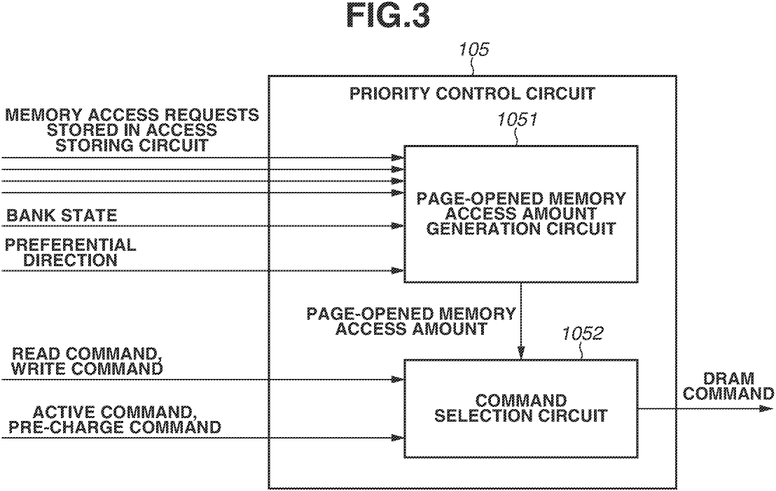

FIG. 3 is a diagram illustrating an example of the configuration of the priority control circuit 105 in FIG. 1. The priority control circuit 105 includes a page-opened memory access amount generation circuit 1051 and a command selection circuit 1052. The preferential direction is input from the read/write control circuit 102 and indicates which of read access and write access is currently preferentially selected.

Based on the bank state, the page-opened memory access amount generation circuit 1051 determines whether the target bank 1011b in each of the memory access requests stored in the access storing circuit 101 opens the target page 1011c. Then, regarding memory access requests in which the request type 1011a matches the preferential direction, the page-opened memory access amount generation circuit 1051 totals the numbers of remaining read/write commands 1011e in memory access requests in which the target pages 1011c are opened according to the determination. The page-opened memory access amount generation circuit 1051 generates the totaled number of remaining read/write commands as the page-opened memory access amount and outputs the page-opened memory access amount to the command selection circuit 1052.

Based on the page-opened memory access amount, the command selection circuit 1052 selects one of a read or write command input from the read/write control circuit 102 and a page control command input from the page control circuit 103 and issues the selected command to the DRAM 110.

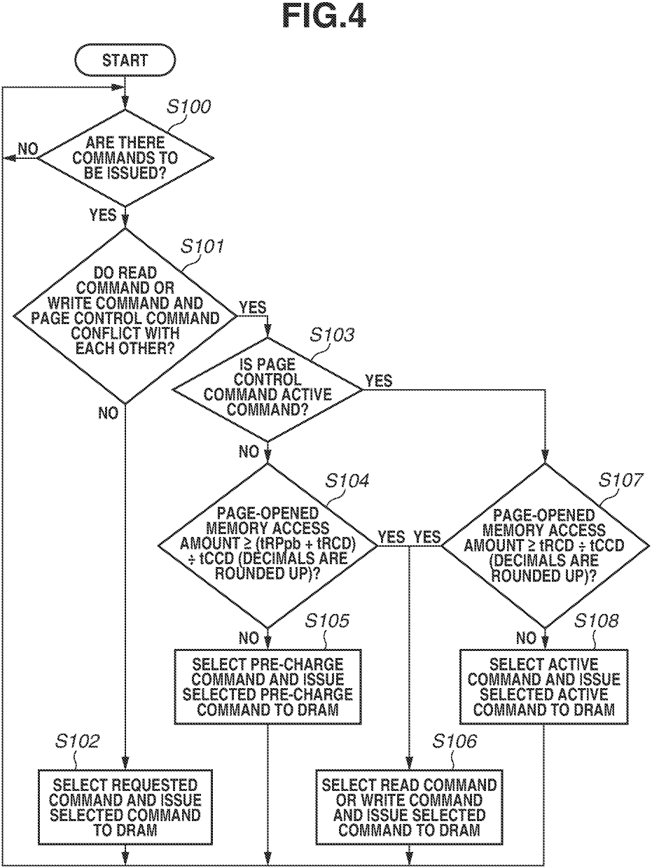

With reference to FIG. 4, the operation of the command selection circuit 1052 is described in further detail.

FIG. 4 is a flowchart illustrating a control method for controlling the command selection circuit 1052 in FIG. 3. In step S100, the command selection circuit 1052 determines whether a read command or a write command is output from the read/write control circuit 102 and an active command or a pre-charge command is output from the page control circuit 103. If a read command or a write command is output from the read/write control circuit 102 and an active command or a pre-charge command is output from the page control circuit 103 (YES in step S100), the processing proceeds to step S101. If a read command or a write command is not output from the read/write control circuit 102 and an active command or a pre-charge command is not output from the page control circuit 103 (NO in step S100), the processing returns to step S100.

In step S101, the command selection circuit 1052 determines whether the read command or the write command and the page control command conflict with each other. If the read command or the write command and the page control command do not conflict with each other (NO in step S101), the processing proceeds to step S102. If the read command or the write command and the page control command conflict with each other (YES in step S101), the processing proceeds to step S103.

In step S102, the command selection circuit 1052 selects the read command, the write command, or the page control command for which an issuance request is made, and issues the selected command to the DRAM 110. Then, the processing returns to step S100.

In step S103, the command selection circuit 1052 determines whether the page control command is an active command. If the page control command is an active command (YES in step S103), the processing proceeds to step S107. If the page control command is not an active command (NO in step S103), the page control command is a pre-charge command, and therefore, the processing proceeds to step S104.

In step S104, the command selection circuit 1052 determines whether the following condition holds true.

(The page-opened memory access amount) ≥ ((tRPpb + tRCD) ÷ tCCD) (decimals are rounded up)

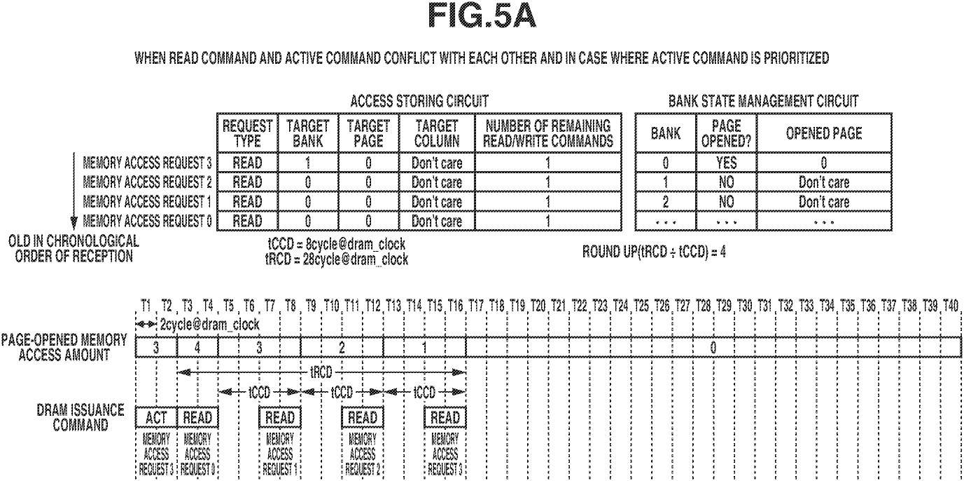

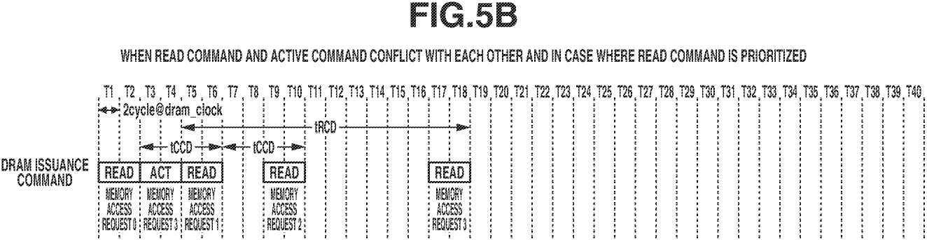

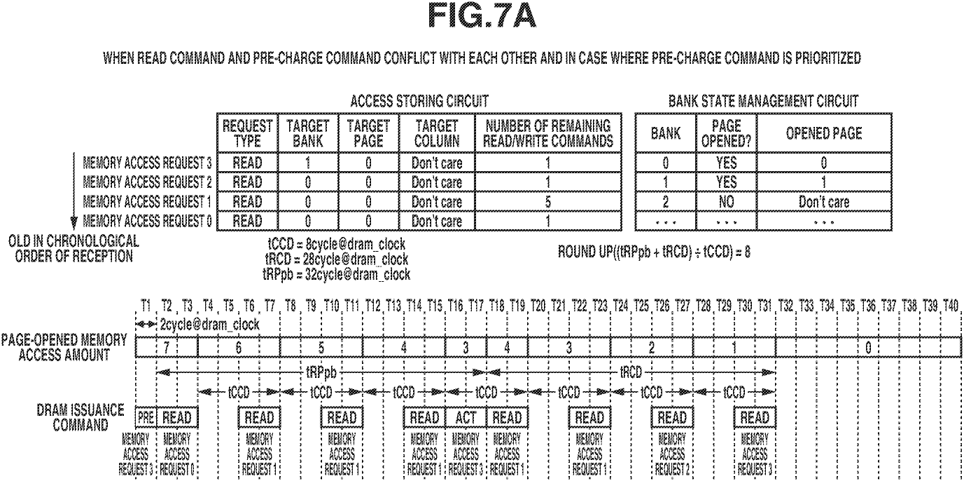

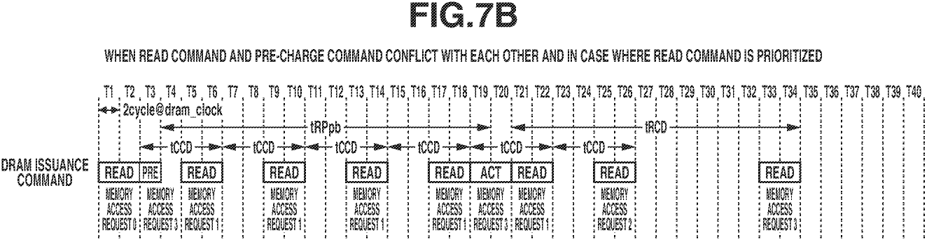

In this condition, tRPpb is a row pre-charge time, and as illustrated in FIGS. 7A and 7B, is the minimum time in which a next active command can be issued after a pre-charge command. As illustrated in FIGS. 5A and 5B, tRCD is a timing constraint period from an active command to a read command or a write command to the same bank. As illustrated in FIGS. 5A and 5B, tCCD is the minimum time in which a next read command (a next write command) can be issued after a read command (a write command).

If the condition in step S104 holds true (YES in step S104), the processing proceeds to step S106. If the condition in step S104 does not hold true (NO in step S104), the processing proceeds to step S105.

In step S107, the command selection circuit 1052 determines whether the following condition holds true.

(The page-opened memory access amount) ≥ (tRCD ÷ tCCD) (decimals are rounded up)

If the condition in step S107 holds true (YES in step S107), the processing proceeds to step S106. If the condition in step S107 does not hold true (NO in step S107), the processing proceeds to step S108.

In step S105, the command selection circuit 1052 selects the pre-charge command and issues the pre-charge command to the DRAM 110. Then, the processing returns to step S100.

In step S106, the command selection circuit 1052 selects the read command or the write command and issues the selected command to the DRAM 110. Then, the processing returns to step S100.

In step S108, the command selection circuit 1052 selects the active command and issues the active command to the DRAM 110. Then, the processing returns to step S100.

Although the maximum number of read or write commands that can be issued during the periods of (tRPpb + tRCD) and tRCD is used as the threshold in steps S104 and S107, the threshold is not limited to this. A value other than the maximum number of read or write commands that can be issued during the periods of (tRPpb + tRCD) and tRCD may be used as the threshold. Consequently, it is possible to adjust the priorities of the read or write command and the page control command.

FIGS. 5A to 8B are diagrams illustrating operation examples (Low-Power Double Data Rate (LPDDR) 4) of the command selection of the command selection circuit 1052 according to the present exemplary embodiment. These operation examples are based on the premise that an LPDDR4 synchronous dynamic random-access memory (SDRAM) is used as the DRAM 110, and the preferential direction is a read command. Timing constraints and the states of memory access requests stored in the access storing circuit 101 and the bank states at the start of a time T1 are illustrated in FIGS. 5A to 8B. The respective memory access requests stored in the access storing circuit 101 are assigned identifiers as in memory access requests 0 to 3 for illustrative purposes.

FIG. 5A is a diagram illustrating an operation example (LPDDR4) where, when a read command (READ) and an active command (ACT) conflict with each other, the command selection circuit 1052 selects the active command at the time T1 according to the present exemplary embodiment. In the memory access requests 0 to 2, a page to be accessed is already opened, and therefore, the read/write control circuit 102 outputs a read command to the memory access request 0. In the memory access request 3, a page in a bank to be accessed is closed, and therefore, the page control circuit 103 outputs an active command to the memory access request 3. At the time T1, the page-opened memory access amount is 3, which is less than the threshold (4 = tRCD ÷ tCCD (decimals are rounded up)). Thus, the priority control circuit 105 selects the active command and issues the active command to the DRAM 110. The issuance of read commands to the memory access requests 0 to 3 is completed at a time T16.

FIG. 5B is a diagram illustrating an operation example (LPDDR4) where, when a read command and an active command conflict with each other, the command selection circuit 1052 selects the read command at the time T1. In this case, the issuance of read commands to the memory access requests 0 to 3 is completed at a time T18. The completion time T18 is later than the read command issuance completion time T16 in FIG. 5A.

Thus, it is desirable that the command selection circuit 1052 should select the active command as illustrated in FIG. 5A.

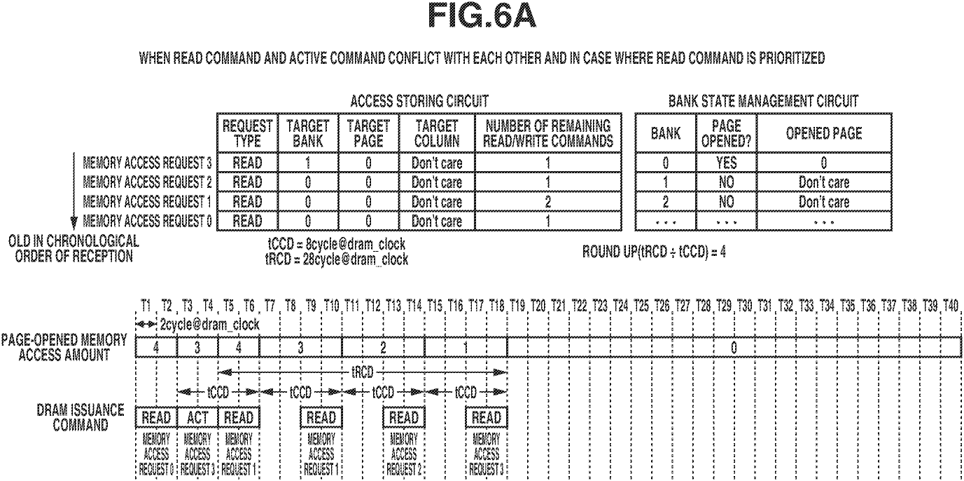

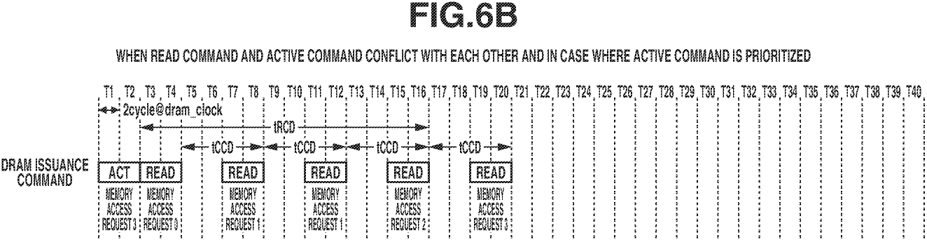

FIG. 6A is a diagram illustrating an operation example (LPDDR4) where, when a read command and an active command conflict with each other, the command selection circuit 1052 selects the read command at the time T1 according to the present exemplary embodiment. In the memory access requests 0 to 2, a page to be accessed is already opened, and therefore, the read/write control circuit 102 outputs a read command to the memory access request 0. In the memory access request 3, a page in a bank to be accessed is closed, and therefore, the page control circuit 103 outputs an active command to the memory access request 3. At the time T1, the page-opened memory access amount is 4, which is greater than or equal to the threshold (4 = tRCD ÷ tCCD (decimals are rounded up)). Thus, the priority control circuit 105 selects the read command and issues the read command to the DRAM 110. The issuance of read commands to the memory access requests 0 to 3 is completed at a time T18.

FIG. 6B is a diagram illustrating an operation example (LPDDR4) where, when a read command and an active command conflict with each other, the command selection circuit 1052 selects the active command at the time T1. In this case, the issuance of read commands to the memory access requests 0 to 3 is completed at a time T20. The completion time T20 is later than the read command issuance completion time T18 in FIG. 6A. Thus, it is desirable that the command selection circuit 1052 should select the read command as illustrated in FIG. 6A.

FIG. 7A is a diagram illustrating an operation example (LPDDR4) where, when a read command and a pre-charge command (PRE) conflict with each other, the command selection circuit 1052 selects the pre-charge command at the time T1 according to the present exemplary embodiment. In the memory access requests 0 to 2, a page to be accessed is already opened, and therefore, the read/write control circuit 102 outputs a read command to the memory access request 0. In the memory access request 3, a page different from a page that should be accessed is opened in a bank to be accessed, and therefore, the page control circuit 103 outputs a pre-charge command to the memory access request 3. At the time T1, the page-opened memory access amount is 7, which is less than the threshold (8 = (tRPpb + tRCD) ÷ tCCD (decimals are rounded up)). Thus, the priority control circuit 105 selects the pre-charge command and issues the pre-charge command to the DRAM 110. The issuance of read commands to the memory access requests 0 to 3 is completed at a time T31.

FIG. 7B is a diagram illustrating an operation example (LPDDR4) where, when a read command and a pre-charge command conflict with each other, the command selection circuit 1052 selects the read command at the time T1. In this case, the issuance of read commands to the memory access requests 0 to 3 is completed at a time T34. The completion time T34 is later than the read command issuance completion time T31 in FIG. 7A. Thus, it is desirable that the command selection circuit 1052 should select the pre-charge command as illustrated in FIG. 7A.

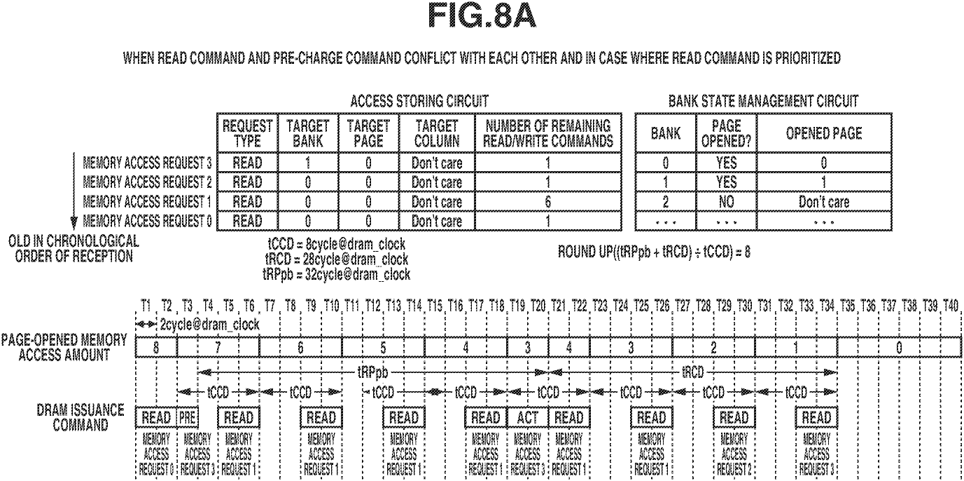

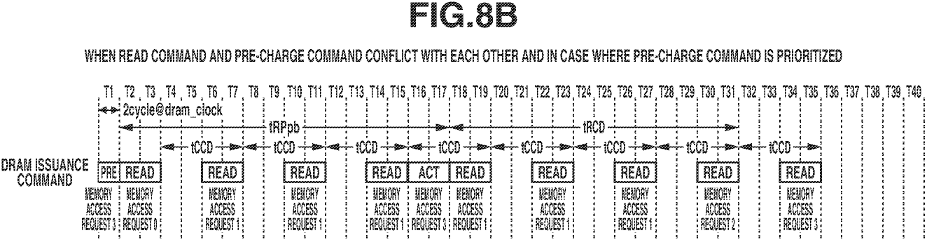

FIG. 8A is a diagram illustrating an operation example (LPDDR4) where, when a read command and a pre-charge command conflict with each other, the command selection circuit 1052 selects the read command at the time T1 according to the present exemplary embodiment. In the memory access requests 0 to 2, a page to be accessed is already opened, and therefore, the read/write control circuit 102 outputs a read command to the memory access request 0. In the memory access request 3, a page different from a page that should be accessed is opened in a bank to be accessed, and therefore, the page control circuit 103 outputs a pre-charge command to the memory access request 3. At the time T1, the page-opened memory access amount is 8, which is greater than or equal to the threshold (8 = (tRPpb + tRCD) ÷ tCCD (decimals are rounded up)). Thus, the priority control circuit 105 selects the read command and issues the read command to the DRAM 110. The issuance of read commands to the memory access requests 0 to 3 is completed at a time T34.

FIG. 8B is a diagram illustrating an operation example (LPDDR4) where, when a read command and a pre-charge command conflict with each other, the command selection circuit 1052 selects the pre-charge command at the time T1. In this case, the issuance of read commands to the memory access requests 0 to 3 is completed at a time T35. The completion time T35 is later than the read command issuance completion time T34 in FIG. 8A.

Thus, it is desirable that the command selection circuit 1052 should select the read command as illustrated in FIG. 8A.

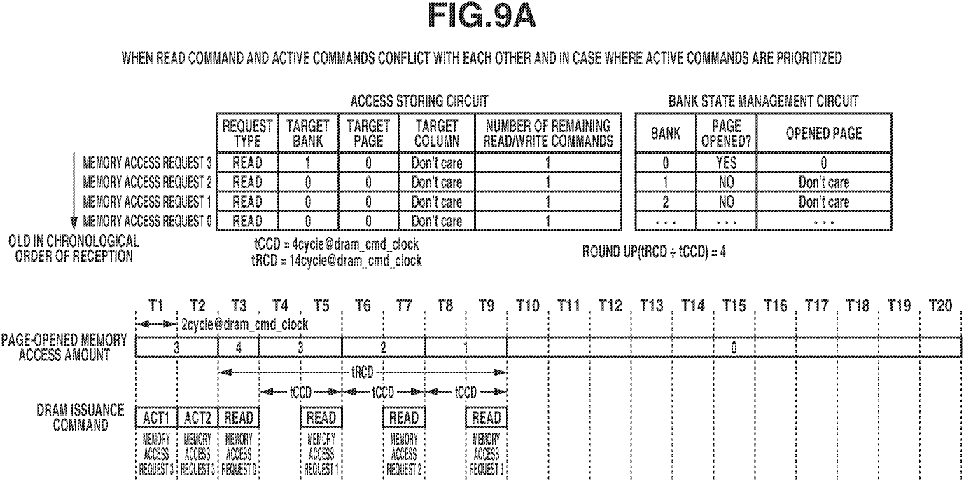

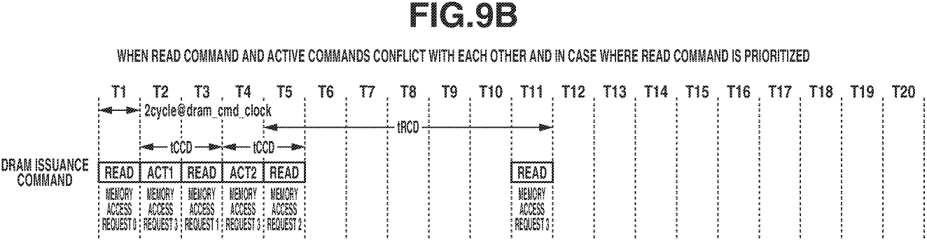

FIGS. 9A to 12B are diagrams illustrating operation examples (LPDDR5) of the command selection of the command selection circuit 1052 according to the present exemplary embodiment. These operation examples are based on the premise that an LPDDR5 SDRAM is used as the DRAM 110, and the preferential direction is a read command. Timing constraints and the states of memory access requests stored in the access storing circuit 101 and the bank states at the start of a time T1 are illustrated in FIGS. 9A to 12B. In a case where a desired page is opened in the LPDDR5 SDRAM, it is necessary to issue two active commands, namely an active command 1 (ACT1) and an active command 2 (ACT2).

FIG. 9A is a diagram illustrating an operation example (LPDDR5) where, when a read command and active commands conflict with each other, the command selection circuit 1052 selects an active command 1 at the time T1 according to the present exemplary embodiment. In the memory access requests 0 to 2, a page to be accessed is already opened, and therefore, the read/write control circuit 102 outputs a read command to the memory access request 0. In the memory access request 3, a page in a bank to be accessed is closed, and therefore, the page control circuit 103 outputs active commands to the memory access request 3. At the time T1, the page-opened memory access amount is 3, which is less than the threshold (4 = tRCD ÷ tCCD (decimals are rounded up)). Thus, the priority control circuit 105 selects an active command 1 and issues the active command 1 to the DRAM 110. The issuance of read commands to the memory access requests 0 to 3 is completed at a time T9.

FIG. 9B is a diagram illustrating an operation example (LPDDR5) where, when a read command and active commands conflict with each other, the command selection circuit 1052 selects the read command at the time T1. In this case, the issuance of read commands to the memory access requests 0 to 3 is completed at a time T11. The completion time T11 is later than the read command issuance completion time T9 in FIG. 9A. Thus, it is desirable that the command selection circuit 1052 should select the read command as illustrated in FIG. 9A.

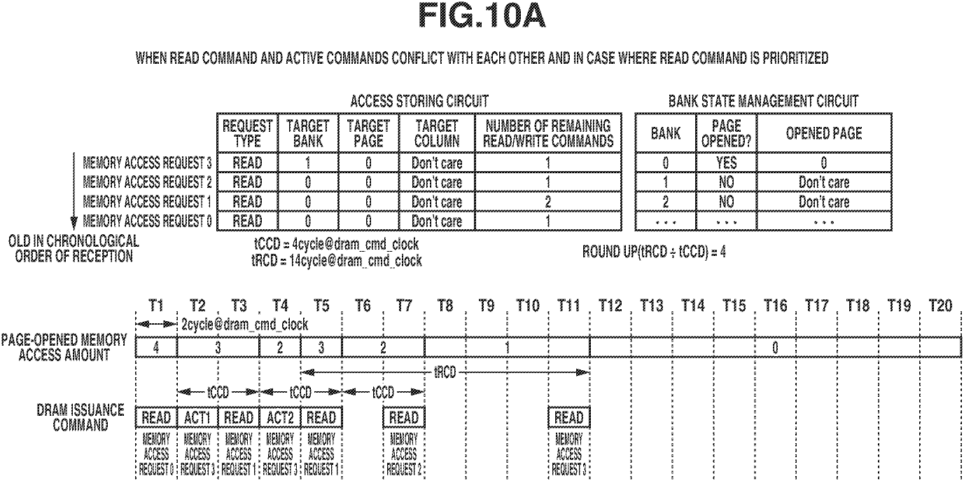

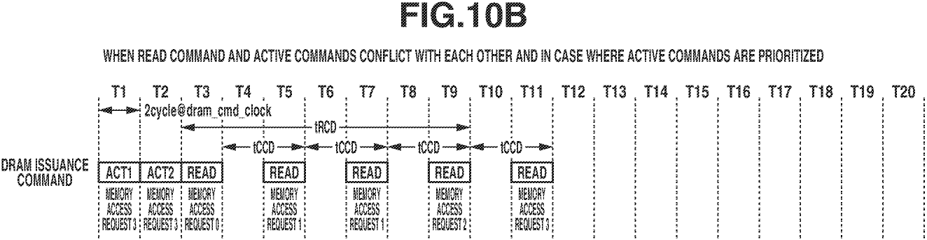

FIG. 10A is a diagram illustrating an operation example (LPDDR5) where, when a read command and active commands conflict with each other, the command selection circuit 1052 selects the read command at the time T1 according to the present exemplary embodiment. In the memory access requests 0 to 2, a page to be accessed is already opened, and therefore, the read/write control circuit 102 outputs a read command to the memory access request 0. In the memory access request 3, a page in a bank to be accessed is closed, and therefore, the page control circuit 103 outputs an active command to the memory access request 3. At the time T1, the page-opened memory access amount is 4, which is greater than or equal to the threshold (4 = tRCD ÷ tCCD (decimals are rounded up)). Thus, the priority control circuit 105 selects the read command and issues the read command to the DRAM 110. The issuance of read commands to the memory access requests 0 to 3 is completed at a time T11.

FIG. 10B is a diagram illustrating an operation example (LPDDR5) where, when a read command and active commands conflict with each other, the command selection circuit 1052 selects an active command 1 at the time T1. In this case, the issuance of read commands to the memory access requests 0 to 3 is completed at a time T11. The completion time T11 is the same as the read command issuance completion time T11 in FIG. 10A.

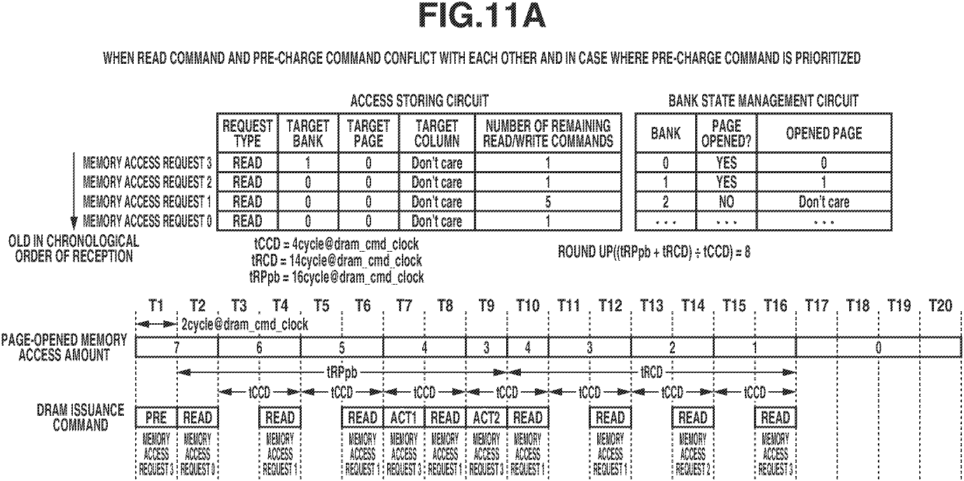

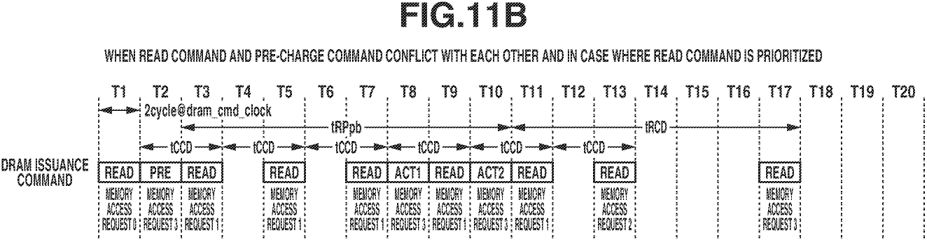

FIG. 11A is a diagram illustrating an operation example (LPDDR5) where, when a read command and a pre-charge command conflict with each other, the command selection circuit 1052 selects the pre-charge command at the time T1 according to the present exemplary embodiment. In the memory access requests 0 to 2, a page to be accessed is already opened, and therefore, the read/write control circuit 102 outputs a read command to the memory access request 0. In the memory access request 3, a page different from a page that should be accessed is opened in a bank to be accessed, and therefore, the page control circuit 103 outputs a pre-charge command to the memory access request 3. At the time T1, the page-opened memory access amount is 7, which is less than the threshold (8 = (tRPpb + tRCD) ÷ tCCD (decimals are rounded up)). Thus, the priority control circuit 105 selects the pre-charge command and issues the pre-charge command to the DRAM 110. The issuance of read commands to the memory access requests 0 to 3 is completed at a time T16.

FIG. 11B is a diagram illustrating an operation example (LPDDR5) where, when a read command and a pre-charge command conflict with each other, the command selection circuit 1052 selects the read command at the time T1. In this case, the issuance of read commands to the memory access requests 0 to 3 is completed at a time T17. The completion time T17 is later than the read command issuance completion time T16 in FIG. 11A. Thus, it is desirable that the command selection circuit 1052 should select the pre-charge command as illustrated in FIG. 11A.

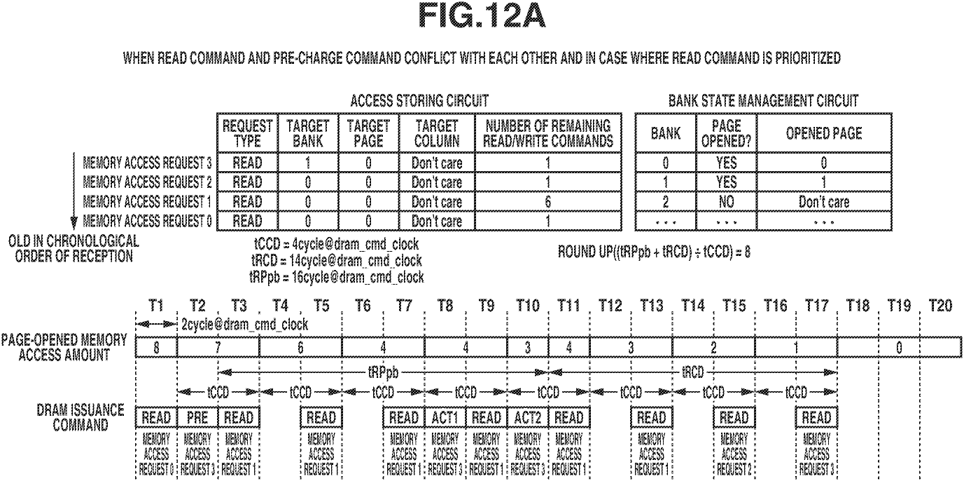

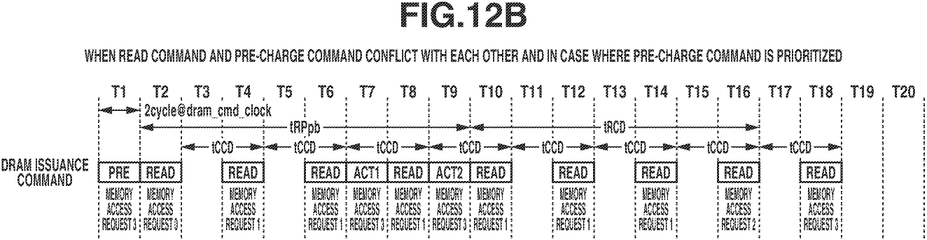

FIG. 12A is a diagram illustrating an operation example (LPDDR5) where, when a read command and a pre-charge command conflict with each other, the command selection circuit 1052 selects the read command at the time T1 according to the present exemplary embodiment. In the memory access requests 0 to 2, a page to be accessed is already opened, and therefore, the read/write control circuit 102 outputs a read command to the memory access request 0. In the memory access request 3, a page different from a page that should be accessed is opened in a bank to be accessed, and therefore, the page control circuit 103 outputs a pre-charge command to the memory access request 3. At the time T1, the page-opened memory access amount is 8, which is greater than or equal to the threshold (8 = (tRPpb + tRCD) ÷ tCCD (decimals are rounded up)). Thus, the priority control circuit 105 selects the read command and issues the read command to the DRAM 110. The issuance of read commands to the memory access requests 0 to 3 is completed at a time T17.

FIG. 12B is a diagram illustrating an operation example (LPDDR5) where, when a read command and a pre-charge command conflict with each other, the command selection circuit 1052 selects the pre-charge command at the time T1. In this case, the issuance of read commands to the memory access requests 0 to 3 is completed at a time T18. The completion time T18 is later than the read command issuance completion time T17 in FIG. 12A. Thus, it is desirable that the command selection circuit 1052 should select the read command as illustrated in FIG. 12A.

As described above, according to the present exemplary embodiment, the memory controller 100 can select any memory access requests from a plurality of memory access requests and issue commands to the DRAM 110. Based on access requests in which pages to be accessed are already opened, the priority control circuit 105 changes the priorities of the commands to be issued to the DRAM 110, whereby it is possible to prevent a decrease in the memory use efficiency of the DRAM 110.

As described above, the DRAM 110 is a dynamic random-access memory. The memory controller 100 issues commands to access the DRAM 110 including a plurality of banks.

The access storing circuit 101 is a storing unit and stores one or more read or write access requests. The read/write control circuit 102 is a generation unit and generates a read command or a write command based on the access requests stored in the access storing circuit 101. The page control circuit 103 is a generation unit and generates a page control command based on the access requests stored in the access storing circuit 101.

The page-opened memory access amount generation circuit 1051 generates a page-opened memory access amount based on a preferential direction from the read/write control circuit 102. The preferential direction indicates which of read and write is prioritized during the current period.

During a period when read is prioritized between read and write, the page-opened memory access amount is the number of read commands based on read access requests in which pages are already opened among the read access requests stored in the access storing circuit 101.

During a period when write is prioritized between read and write, the page-opened memory access amount is the number of write commands based on write access requests in which pages are already opened among the write access requests stored in the access storing circuit 101.

In step S101, if the read command or the write command generated by the read/write control circuit 102 and the page control command generated by the page control circuit 103 conflict with each other, the processing proceeds to step S103.

In step S103, if the page control command is an active command, the processing proceeds to step S107. If the page control command is a pre-charge command, the processing proceeds to step S104.

In steps S104 and S107, based on access requests in which pages are already opened among the access requests stored in the access storing circuit 101, the processing proceeds to step S105, S106, or S108. Specifically, based on the number of read commands or write commands based on the access requests in which the pages are already opened among the access requests stored in the access storing circuit 101, the processing proceeds to step S105, S106, or S108. In this case, the priority control circuit 105 functions as an issuance unit and issues either of the read command or the write command generated by the read/write control circuit 102 and the page control command generated by the page control circuit 103 to the DRAM 110.

In step S107, if the page-opened memory access amount is less than a first threshold, the processing proceeds to step S108. If the page-opened memory access amount is greater than or equal to the first threshold, the processing proceeds to step S106.

The page-opened memory access amount is the number of read commands or write commands based on the access requests in which the pages are already opened among the access requests stored in the access storing circuit 101.

The first threshold is (tRCD ÷ tCCD) (decimals are rounded up). tRCD is a timing constraint period from an active command to a read command or a write command to the same bank. That is, the first threshold is a value based on the number of read commands or write commands that can be issued during a timing constraint period from an active command to a read command or a write command to the same bank. For example, the first threshold is the maximum number of read commands or write commands that can be issued during a timing constraint period from an active command to a read command or a write command to the same bank.

In step S104, if the page-opened memory access amount is less than a second threshold, the processing proceeds to step S105. If the page-opened memory access amount is greater than or equal to the second threshold, the processing proceeds to step S106.

The second threshold is ((tRPpb + tRCD) ÷ tCCD) (decimals are rounded up). (tRPpb + tRCD) is a timing constraint period from a pre-charge command to a read command or a write command to the same bank. That is, the second threshold is a value based on the number of read commands or write commands that can be issued during a timing constraint period from a pre-charge command to a read command or a write command to the same bank. For example, the second threshold is the maximum number of read commands or write commands that can be issued during a timing constraint period from a pre-charge command to a read command or a write command to the same bank.

In step S105, the priority control circuit 105 issues the pre-charge command generated by the page control circuit 103 to the DRAM 110. In step S106, the priority control circuit 105 issues the read command or the write command generated by the read/write control circuit 102 to the DRAM 110. In step S108, the priority control circuit 105 issues the active command generated by the page control circuit 103 to the DRAM 110.

As described above, according to the present exemplary embodiment, based on the number of read commands or write commands based on access requests in which pages to be accessed are already opened, the priority control circuit 105 changes the priorities of commands to be issued to the DRAM 110. Consequently, it is possible to prevent a decrease in the memory use efficiency of the DRAM 110.

The configuration of the memory controller 100 according to a second exemplary embodiment is similar to the memory controller 100 according to the first exemplary embodiment in FIG. 1. The memory controller 100 according to the second exemplary embodiment is different from the memory controller 100 according to the first exemplary embodiment in the access storing circuit 101, the read/write control circuit 102, and the priority control circuit 105. In the second exemplary embodiment, as the page-opened memory access amount, the amount of data to be accessed is used instead of the number of read/write commands. In the second exemplary embodiment, components similar to those in the first exemplary embodiment are not described.

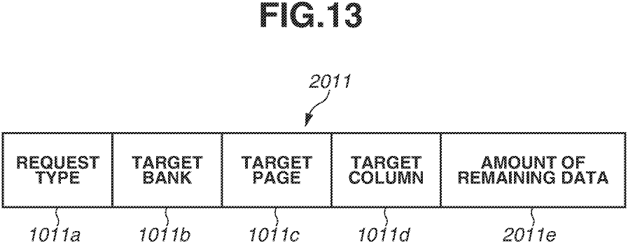

First, the access storing circuit 101 is described. FIG. 13 is a diagram illustrating an example of the configuration of an entry 2011 in the access storing circuit 101 according to the second exemplary embodiment. In the access storing circuit 101, m entries 2011 as illustrated in FIG. 13 are present. The entry 2011 in FIG. 13 is obtained by changing the “number of remaining read/write commands” field 1011e in the entry 1011 in FIG. 2 to an “amount of remaining data” field 2011e. The entry 2011 includes the “request type” field 1011a, the “target bank” field 1011b, the “target page” field 1011c, the “target column” field 1011d, and the “amount of remaining data” field 2011e.

The access storing circuit 101 converts a memory access request received from the bus master 120 to correspond to the fields 1011a to 1011d and 2011e and stores the fields 1011a to 1011d and 2011e. The “amount of remaining data” field 2011e stores the amount of remaining data 2011e to be accessed by the memory access request stored in the entry 2011. The amount of data is not limited to the number of bytes, and may be a burst length on a particular bus. If 1 is set in the update field, the access storing circuit 101 updates the “target column” field 1011d in the entry 2011 indicated by the entry number field to a beginning column address to be accessed by a next DRAM command. The access storing circuit 101 also updates the “amount of remaining data” field 2011e to a value obtained by subtracting the amount of data accessed by a read/write command from the amount of remaining data 2011e.

Next, the read/write control circuit 102 is described. If the read/write control circuit 102 issues the last read command or write command to be executed according to a memory access request, the processing of the corresponding memory access request is completed. Thus, the read/write control circuit 102 generates an entry control signal to delete the corresponding entry 2011 from the access storing circuit 101. If, on the other hand, the read/write control circuit 102 issues a read command or a write command that is not the last, the read/write control circuit 102 generates an entry control signal to update the corresponding entry 2011 in the access storing circuit 101. The determination of whether the issued read command or write command is the last is made by the read/write control circuit 102 based on whether the amount of remaining data 2011e in the entry 2011 is less than or equal to the amount of data to be accessed by the issued read command or write command.

Finally, the priority control circuit 105 is described. As illustrated in FIG. 3, the priority control circuit 105 includes the page-opened memory access amount generation circuit 1051 and the command selection circuit 1052. Based on the bank state, the page-opened memory access amount generation circuit 1051 determines whether the target bank 1011b in each of the memory access requests stored in the access storing circuit 101 opens the target page 1011c. Then, regarding memory access requests in which the request type 1011a matches the preferential direction, the page-opened memory access amount generation circuit 1051 totals the amounts of remaining data 2011e in memory access requests in which the target pages 1011c are opened according to the determination. The page-opened memory access amount generation circuit 1051 generates the totaled amount of remaining data as the page-opened memory access amount and outputs the page-opened memory access amount to the command selection circuit 1052.

Based on the page-opened memory access amount, the command selection circuit 1052 selects one of a read or write command input from the read/write control circuit 102 and a page control command input from the page control circuit 103 and issues the selected command to the DRAM 110.

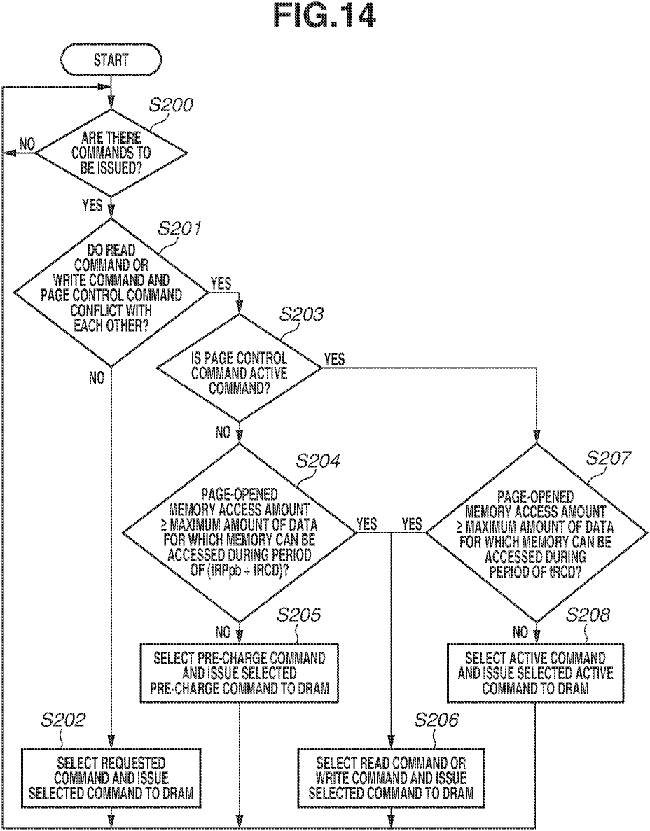

With reference to FIG. 14, the operation of the command selection circuit 1052 is described in further detail.

FIG. 14 is a flowchart illustrating a control method for controlling the command selection circuit 1052 according to the second exemplary embodiment. In step S200, the command selection circuit 1052 determines whether a read command or a write command is output from the read/write control circuit 102 and an active command or a pre-charge command is output from the page control circuit 103. If a read command or a write command is output from the read/write control circuit 102 and an active command or a pre-charge command is output from the page control circuit 103 (YES in step S200), the processing proceeds to step S201. If a read command or a write command is not output from the read/write control circuit 102 and an active command or a pre-charge command is not output from the page control circuit 103 (NO in step S200), the processing returns to step S200.

In step S201, the command selection circuit 1052 determines whether the read command or the write command and the page control command conflict with each other. If the read command or the write command and the page control command do not conflict with each other (NO in step S201), the processing proceeds to step S202. If the read command or the write command and the page control command conflict with each other (YES in step S201), the processing proceeds to step S203.

In step S202, the command selection circuit 1052 selects the read command, the write command, or the page control command for which an issuance request is made, and issues the selected command to the DRAM 110. Then, the processing returns to step S200.

In step S203, the command selection circuit 1052 determines whether the page control command is an active command. If the page control command is an active command (YES in step S203), the processing proceeds to step S207. If the page control command is not an active command (NO in step S203), the page control command is a pre-charge command, and therefore, the processing proceeds to step S204.

In step S204, the command selection circuit 1052 determines whether the following condition holds true.

(The page-opened memory access amount) ≥ (the maximum amount of data for which the memory can be accessed during the period of (tRPpb + tRCD))

If the condition in step S204 holds true (YES in step S204), the processing proceeds to step S206. If the condition in step S204 does not hold true (NO in step S204), the processing proceeds to step S205.

In step S207, the command selection circuit 1052 determines whether the following condition holds true.

(The page-opened memory access amount) ≥ (the maximum amount of data for which the memory can be accessed during the period of tRCD)

If the condition in step S207 holds true (YES in step S207), the processing proceeds to step S206. If the condition in step S207 does not hold true (NO in step S207), the processing proceeds to step S208.

In step S205, the command selection circuit 1052 selects the pre-charge command and issues the selected pre-charge command to the DRAM 110. Then, the processing returns to step S200.

In step S206, the command selection circuit 1052 selects the read command or the write command and issues the selected command to the DRAM 110. Then, the processing returns to step S200.

In step S208, the command selection circuit 1052 selects the active command and issues the selected active command to the DRAM 110. Then, the processing returns to step S200.

Although the maximum amount of data for which the memory can be accessed during the periods of (tRPpb + tRCD) and tRCD is used as the threshold in steps S204 and S207, the threshold is not limited to this. Thus, a value other than the maximum amount of data for which the memory can be accessed during the periods of (tRPpb + tRCD) and tRCD may be used as the threshold. Consequently, it is possible to adjust the priorities of the read or write command and the page control command.

As described above, the page-opened memory access amount generation circuit 1051 generates a page-opened memory access amount based on a preferential direction from the read/write control circuit 102. The preferential direction indicates which of read and write is prioritized during the current period.

During a period when read is prioritized between read and write, the page-opened memory access amount is the amount of read data based on read access requests in which pages are already opened among the read access requests stored in the access storing circuit 101.

During a period when write is prioritized between read and write, the page-opened memory access amount is the amount of write data based on write access requests in which pages are already opened among the write access requests stored in the access storing circuit 101.

In step S201, if the read command or the write command generated by the read/write control circuit 102 and the page control command generated by the page control circuit 103 conflict with each other, the processing proceeds to step S203.

In step S203, if the page control command is an active command, the processing proceeds to step S207. If the page control command is a pre-charge command, the processing proceeds to step S204.

In steps S204 and S207, based on access requests in which pages are already opened among the access requests stored in the access storing circuit 101, the processing proceeds to step S205, S206, and S208. Specifically, based on the amount of read or write data based on the access requests in which the pages are already opened among the access requests stored in the access storing circuit 101, the processing proceeds to step S205, S206, or S208. In this case, the priority control circuit 105 issues either of the read command or the write command generated by the read/write control circuit 102 and the page control command generated by the page control circuit 103 to the DRAM 110.

In step S207, if the page-opened memory access amount is less than a first threshold, the processing proceeds to step S208. If the page-opened memory access amount is greater than or equal to the first threshold, the processing proceeds to step S206.

The page-opened memory access amount is the amount of read or write data based on the access requests in which the pages are already opened among the access requests stored in the access storing circuit 101.

The first threshold is the maximum amount of data that can be read or written during the period of tRCD. The period of tRCD is a timing constraint period from an active command to a read command or a write command to the same bank. That is, the first threshold is the maximum amount of data that can be read or written during a timing constraint period from an active command to a read command or a write command to the same bank.

In step S204, if the page-opened memory access amount is less than a second threshold, the processing proceeds to step S205. If the page-opened memory access amount is greater than or equal to the second threshold, the processing proceeds to step S206.

The second threshold is the maximum amount of data that can be read or written during the period of (tRPpb + tRCD). The period of (tRPpb + tRCD) is a timing constraint period from a pre-charge command to a read command or a write command to the same bank. That is, the second threshold is the maximum amount of data that can be read or written during a timing constraint period from a pre-charge command to a read command or a write command to the same bank.

In step S205, the priority control circuit 105 issues the pre-charge command generated by the page control circuit 103 to the DRAM 110. In step S206, the priority control circuit 105 issues the read command or the write command generated by the read/write control circuit 102 to the DRAM 110. In step S208, the priority control circuit 105 issues the active command generated by the page control circuit 103 to the DRAM 110.

As described above, according to the present exemplary embodiment, based on the amount of read or write data based on access requests in which pages to be accessed are already opened, the priority control circuit 105 changes the priorities of commands to be issued to the DRAM 110. Consequently, it is possible to prevent a decrease in the memory use efficiency of the DRAM 110.

All the above exemplary embodiments merely illustrate specific examples for carrying out the present disclosure, and the technical scope of the present disclosure is not interpreted in a limited manner based on these exemplary embodiments. That is, the present disclosure can be carried out in various ways without departing from the technical idea or the main feature of the present disclosure.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-053738, filed Mar. 29, 2022, which is hereby incorporated by reference herein in its entirety.

What is claimed is:

1. A memory controller that issues a command to access a memory including a plurality of banks, the memory controller comprising:
a storing unit configured to store one or more read or write access requests;
a first generation unit configured to generate a read command or a write command based on the access requests stored in the storing unit;
a second generation unit configured to generate a page control command based on the access requests stored in the storing unit; and
an issuance unit configured to, in a case where the read command or the write command generated by the first generation unit and the page control command generated by the second generation unit conflict with each other, then based on access requests in which pages are already opened among the access requests stored in the storing unit, issue either of the read command or the write command generated by the first generation unit and the page control command generated by the second generation unit to the memory.

2. The memory controller according to claim 1, wherein based on the number of read commands or write commands based on the access requests in which the pages are already opened among the access requests stored in the storing unit, the issuance unit issues either of the read command or the write command generated by the first generation unit and the page control command generated by the second generation unit to the memory.

3. The memory controller according to claim 2,
wherein in a case where the page control command is an active command, and the number of read commands or write commands based on the access requests in which the pages are already opened among the access requests stored in the storing unit is less than a first threshold, the issuance unit issues the active command generated by the second generation unit to the memory, and
wherein in a case where the page control command is an active command, and the number of read commands or write commands based on the access requests in which the pages are already opened among the access requests stored in the storing unit is greater than or equal to the first threshold, the issuance unit issues the read command or the write command generated by the first generation unit to the memory.

4. The memory controller according to claim 3, wherein the first threshold is a value based on the number of read commands or write commands that can be issued during a timing constraint period from an active command to a read command or a write command to the same bank.

5. The memory controller according to claim 4, wherein the first threshold is the maximum number of read commands or write commands that can be issued during a timing constraint period from an active command to a read command or a write command to the same bank.

6. The memory controller according to claim 2,
wherein in a case where the page control command is a pre-charge command, and the number of read commands or write commands based on the access requests in which the pages are already opened among the access requests stored in the storing unit is less than a second threshold, the issuance unit issues the pre-charge command generated by the second generation unit to the memory, and
wherein in a case where the page control command is a pre-charge command, and the number of read commands or write commands based on the access requests in which the pages are already opened among the access requests stored in the storing unit is greater than or equal to the second threshold, the issuance unit issues the read command or the write command generated by the first generation unit to the memory.

7. The memory controller according to claim 6, wherein the second threshold is a value based on the number of read commands or write commands that can be issued during a timing constraint period from a pre-charge command to a read command or a write command to the same bank.

8. The memory controller according to claim 7, wherein the second threshold is the maximum number of read commands or write commands that can be issued during a timing constraint period from a pre-charge command to a read command or a write command to the same bank.

9. The memory controller according to claim 1, wherein based on an amount of read or write data based on the access requests in which the pages are already opened among the access requests stored in the storing unit, the issuance unit issues either of the read command or the write command generated by the first generation unit and the page control command generated by the second generation unit to the memory.

10. The memory controller according to claim 9,
wherein in a case where the page control command is an active command, and the amount of read or write data based on the access requests in which the pages are already opened among the access requests stored in the storing unit is less than a first threshold, the issuance unit issues the active command generated by the second generation unit to the memory, and
wherein in a case where the page control command is an active command, and the amount of read or write data based on the access requests in which the pages are already opened among the access requests stored in the storing unit is greater than or equal to the first threshold, the issuance unit issues the read command or the write command generated by the first generation unit to the memory.

11. The memory controller according to claim 10, wherein the first threshold is the maximum amount of data that can be read or written during a timing constraint period from an active command to a read command or a write command to the same bank.

12. The memory controller according to claim 9,
wherein in a case where the page control command is a pre-charge command, and the amount of read or write data based on the access requests in which the pages are already opened among the access requests stored in the storing unit is less than a second threshold, the issuance unit issues the pre-charge command generated by the second generation unit to the memory, and
wherein in a case where the page control command is a pre-charge command, and the amount of read or write data based on the access requests in which the pages are already opened among the access requests stored in the storing unit is greater than or equal to the second threshold, the issuance unit issues the read command or the write command generated by the first generation unit to the memory.

13. The memory controller according to claim 12, wherein the second threshold is the maximum amount of data that can be read or written during a timing constraint period from a pre-charge command to a read command or a write command to the same bank.

14. The memory controller according to claim 2,
wherein during a period when read is prioritized between read and write, then based on the number of read commands based on read access requests in which pages are already opened among read access requests stored in the storing unit, the issuance unit issues either of the read command generated by the first generation unit and the page control command generated by the second generation unit to the memory, and
wherein during a period when write is prioritized between read and write, then based on the number of write commands based on write access requests in which pages are already opened among write access requests stored in the storing unit, the issuance unit issues either of the write command generated by the first generation unit and the page control command generated by the second generation unit to the memory.

15. The memory controller according to claim 9,
wherein during a period when read is prioritized between read and write, then based on an amount of read data based on read access requests in which pages are already opened among read access requests stored in the storing unit, the issuance unit issues either of the read command generated by the first generation unit and the page control command generated by the second generation unit to the memory, and
wherein during a period when write is prioritized between read and write, then based on an amount of write data based on write access requests in which pages are already opened among write access requests stored in the storing unit, the issuance unit issues either of the write command generated by the first generation unit and the page control command generated by the second generation unit to the memory.

16. A control method for controlling a memory controller that includes a storing unit configured to store one or more read or write access requests and issues a command to access a memory including a plurality of banks, the control method comprising:
as first generation, generating a read command or a write command based on the access requests stored in the storing unit;
as second generation, generating a page control command based on the access requests stored in the storing unit; and
in a case where the read command or the write command generated by the first generation and the page control command generated by the second generation conflict with each other, then based on access requests in which pages are already opened among the access requests stored in the storing unit, issuing either of the read command or the write command generated by the first generation and the page control command generated by the second generation to the memory.

17. A non-transitory storage medium storing a program causing a memory controller that includes a storing unit configured to store one or more read or write access requests and issues a command to access a memory including a plurality of banks to execute a control method, the control method comprising:
as first generation, generating a read command or a write command based on the access requests stored in the storing unit;
as second generation, generating a page control command based on the access requests stored in the storing unit; and
in a case where the read command or the write command generated by the first generation and the page control command generated by the second generation conflict with each other, then based on access requests in which pages are already opened among the access requests stored in the storing unit, issuing either of the read command or the write command generated by the first generation and the page control command generated by the second generation to the memory.
